(19) United States
(12) Patent Application Publication
(10) Pub. No.: US 2006/0006913 A1
(43) Pub. Date: Jan. 12, 2006

(54) Integrated circuit comprising series-connected subassemblies

(75) Inventors: Daniel Chatroux, Montelimar (FR); Marc Belleville, Saint Egreve (FR)

Correspondence Address: OLIFF & BERRIDGE, PLC, P.O. BOX 19928, ALEXANDRIA, VA, 22320, US

(73) Assignee: COMMISSARIAT A L'ENERGIE ATOMIQUE, F-75752 PARIS (FR)

(21) Appl. No.: 10/534,462

(22) PCT Filed: Nov. 21, 2003
(86) PCT No.: PCT/FR03/03449

§ 371 Date: May 11, 2005

(30) Foreign Application Priority Data
Nov. 25, 2002 (FR) 02/14763

(51) Int. Cl. H03L 7/00

(52) U.S. Cl. 327/141

(57) ABSTRACT

The integrated circuit comprises subassemblies connected in series enabling synchronization of the subassemblies to be achieved in simple manner. Each subassembly comprises a first and a second power supply terminal and a clock input. The subassemblies are connected in series to the terminals of a voltage supply source so that the same current flows through the different subassemblies. The clock input of each subassembly is connected to a common clock circuit by means of devices for shifting the clock signal levels, for example comprising capacitors and/or transistors. Each subassembly can comprise a decoupling capacitor and a voltage limiting circuit between its first and second power supply terminals.

### BACKGROUND OF THE INVENTION

The invention relates to an integrated circuit comprising at least a digital part comprising a large number of elementary transistors connected to one another so as to form a plurality of functional elements, the functional elements being grouped in subassemblies each comprising a first and a second electrical supply terminal and a clock input, the subassemblies being connected in series by means of their supply terminals to the terminals of a voltage supply source.

### STATE OF THE ART

Digital integrated circuits like microprocessors, microcontrollers, memories, etc . . . are made up of an ever increasing number of elementary transistors of smaller and smaller size. It is well known that according to Moore's law, the number of transistors on a silicon surface doubles every 18 months. Thus, every 18 months, on the same silicon substrate, the number of integrated circuits doubles and the size of each of them decreases. This reduction of size enables increased operating frequencies. The reduction of the size of the transistors imposes a decrease of the maximum supply voltage able to be supported by the transistors. The increase of the number of transistors imposes higher supply currents. This current also increases when the clock frequency is higher. Current supply voltages are about one volt. The next generations of integrated circuits will be supplied by voltages of less than one volt. Generally, integrated circuits are supplied by a voltage supply of identical value to that of each of the elementary functional elements.

The decrease of the supply voltages of these digital integrated circuits and the increase at the same time of the current consumed gives rise to problems of design and of voltage supply energy losses at the level of the wires and current transmission tracks and of the component supply connections.

U.S. Pat. No. 5,703,790 proposes series connection of supply terminals of two processors enabling the latter to be supplied by a higher supply voltage. The clock frequency of the second processor is controlled by a control circuit according to the supply voltage of this second processor. Control is performed by comparing the supply voltage of the second processor with a reference voltage. The difference between the two tensions then determines the clock frequency of the second processor. A shunt regulator fitted in parallel with the second processor enables a part of the current coming from the first processor to be absorbed when control of the clock frequency of the second processor does not enable a sufficient current to be absorbed.

As the clocks of the two processors are different, the current peaks of the two processors are not synchronized. The control circuit only operates on the recurrence frequency of the second peaks so as to control the mean current of the second processor. It is then not possible to operate without decoupling capacitors connected to the supply terminals of the processors. A current peak of the second processor would in fact give rise to a destructive voltage surge at the terminals of the first processor, whereas at the same time the second processor would not have a sufficient value at its terminals. The problem is similar when current peaks of the first processor occur except if the second processor is protected by the shunt regulator, if the latter is dimensioned for this current and if it is able to dissipate the corresponding energy. In this case, the energy sent to the supply terminals of the second processor could in fact be dissipated instead of being stored in the decoupling capacitor.

The decoupling capacitors are energy reserves at the terminals of the processors. These energy reserves have to be sufficient to supply the current to the processors during the transient regulation phases of the voltage which acts by variation of the current consumed by the second processor. The dimensioning of these decoupling capacitors and the energy reserve they constitute has to be adapted to the time response performances of the regulation. As regulation by action on the current of the second processor is performed by control of the clock frequency of the latter, the decoupling capacitors have to be dimensioned to supply energy during several clock cycles. If the control circuit switches between operation at high frequency and operation at low frequency according to U.S. Pat. No. 5,703,790, the decoupling capacitors have to be of high value to be suitable for the often long time constants of this regulation mode as operation is in wave trains successively at high frequency and low frequency. Technological problems are then encountered in achieving these decoupling capacitors, of high value in low voltage, that have to supply the current pulses.

### OBJECT OF THE INVENTION

The object of the invention is to remedy these shortcomings and, more particularly, to avoid problems of design and of low voltage power supply energy losses at high current while ensuring synchronization of the subassemblies of an integrated circuit and a simple architecture of an integrated circuit.

According to the invention, this object is achieved by the fact that the clock input of each subassembly is connected to a common clock circuit and that the clock input of at least one subassembly is connected to the common clock circuit by means of a device for shifting the levels of the clock signal.

According to one development of the invention, the subassemblies are formed in such a way that the sum of the instantaneous supply currents flowing through the elementary functional elements of a subassembly is close to that of the other subassemblies.

According to another development of the invention, the clock inputs of at least two adjacent subassemblies are connected by a device for shifting the clock signal levels.

The device for shifting the clock signal levels can comprise at least one capacitor and/or at least one transistor.

According to a preferred embodiment, each of the subassemblies comprises a voltage limiting circuit connected between its power supply terminals and preferably comprising a diode or a transistor.

### BRIEF DESCRIPTION OF THE DRAWINGS

Other advantages and features will become more clearly apparent from the following description of particular embodiments of the invention given as non-restrictive examples only and represented in the accompanying drawings, in which:

FIGS. 1 and 2 represent two particular embodiments of an integrated circuit according to the invention.

FIGS. 3, 4 and 5 represent different particular embodiments of a subassembly of an integrated circuit according to the invention.

### DESCRIPTION OF PARTICULAR EMBODIMENTS

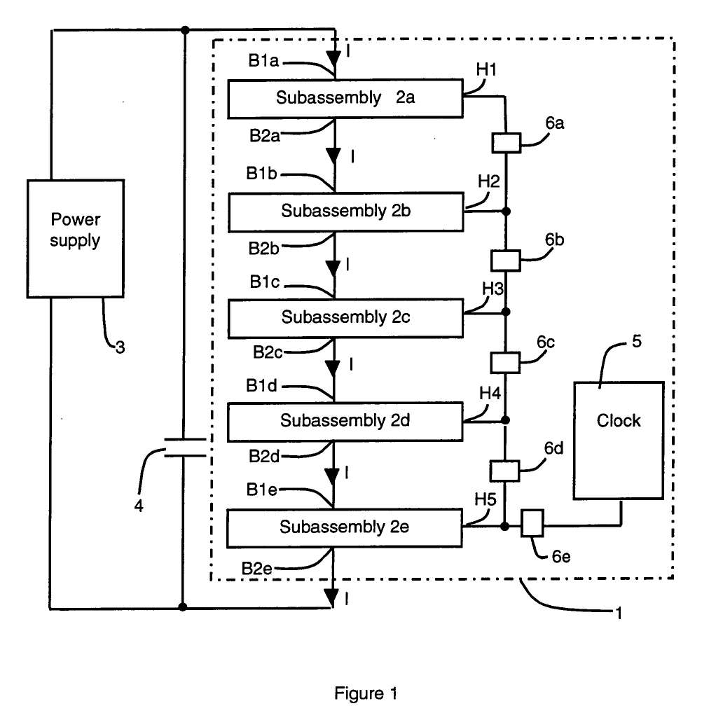

The integrated circuit represented in FIG. 1 comprises several subassemblies 2 (five subassemblies 2a to 2e in FIG. 1). The subassemblies each comprise a first power supply terminal B1, a second power supply terminal B2 and a clock input, respectively H1 to H5. The subassemblies are connected in series, by means of their power supply terminals B1 and B2, to the terminals of a voltage supply source 3, connected in parallel with a decoupling capacitor 4. The same current, noted I, flows through the different subassemblies. The clock inputs H1 to H5 of the subassemblies 2a to 2e are connected to a common clock circuit 5 is by means of devices 6,7 for shifting the clock signal levels. Shifting the clock signal levels consists in applying clock signals to the different subassemblies 2, the voltage level of which signals is adapted to the different supply voltages present at the terminals B1 and B2 of the different subassemblies 2. This does not, as in certain known systems, merely involve applying a single clock signal to different circuits of the system, supplied in parallel or independent manner (see in particular U.S. Pat. No. 5,486,783). The voltage shift of the tension clock signal levels is necessary to compensate the potential differences dues to power supply of the different subassemblies 2 in series.

In FIG. 1, the clock inputs of two adjacent subassemblies (i.e. the power supply terminals B1 and B2 whereof are connected) are connected by a device 6 for shifting the clock signal levels, respectively 6a between the clock inputs H1 and H2, 6b between the clock inputs H2 and H3, 6c between the clock inputs H3 and H4, and 6d between the clock inputs H4 and H5. The clock input (H5) of one of the subassemblies (2e) situated at one end of the series can be advantageously connected by a device 6e for shifting the clock signal levels on output of the common clock circuit 5. The device 6 for shifting the clock signal levels, known to the man of the art, enables the clock signal (or any other signal) to be transmitted while shifting the levels in identical or independent manner.

A device 6 for shifting the clock signal levels can for example be formed by a simple capacitor, or by a transistor-based circuit or by a transistor- and capacitor-based circuit, for example of the type described in the article “Low power CMOS level shifters by bootstrapping technique” (Electronics Letters 1^{st} Aug. 2002, Vol. 38 No. 16).

It should be noted that FIG. 1, and also the other figures, only represents certain types of connections:power supply and clock connections. Other connections can coexist between the subassemblies for example for data transmission, these other connections being able to comprise complex devices such as for example devices for shifting signal levels.

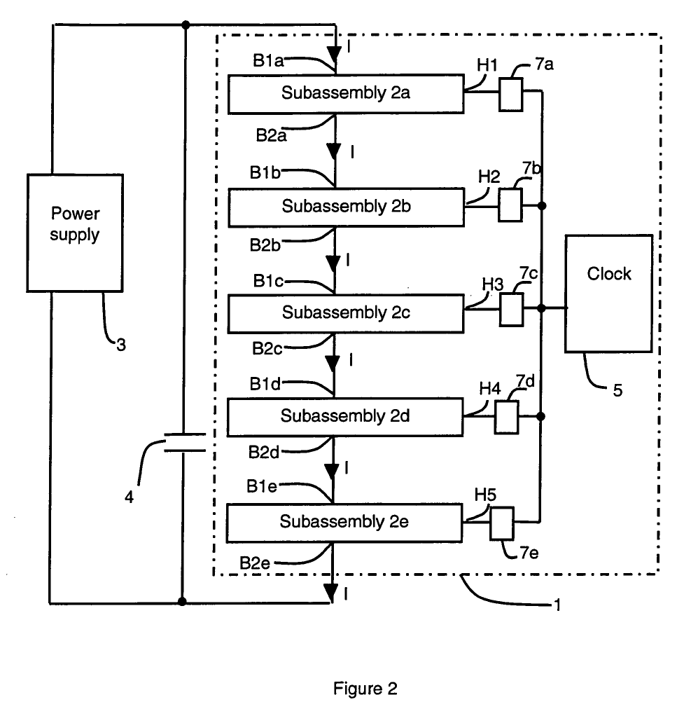

According to another particular embodiment, represented in FIG. 2, the clock input, respectively H1 to H5, of a subassembly, respectively 2a to 2e, is connected to a clock circuit output 5 by means of a device 7 for shifting the clock signal levels (respectively 7a to 7e) of the same type as the device 6 of FIG. 1.

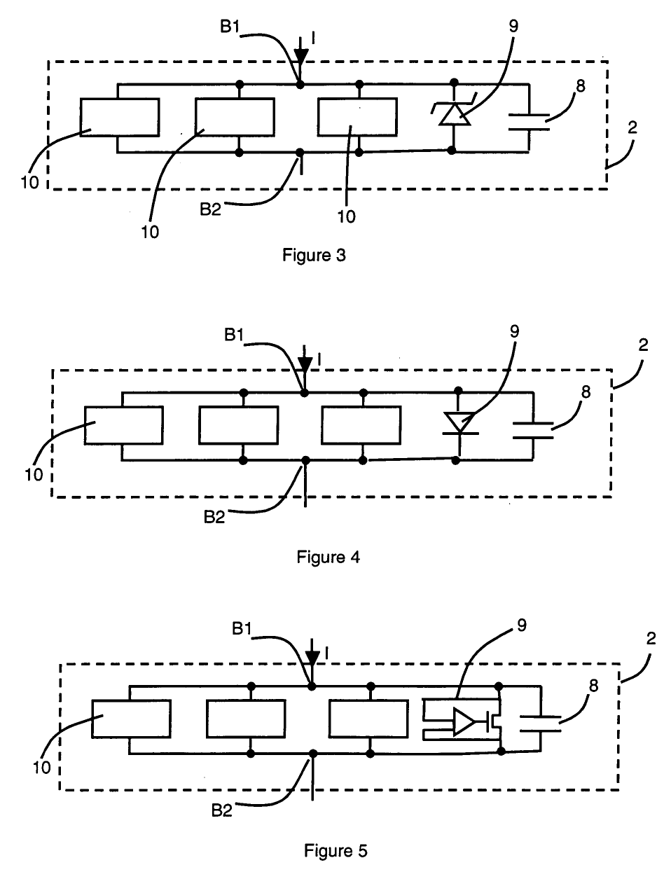

As represented in FIGS. 3 to 5, a subassembly 2 comprises a decoupling capacitor 8 and a voltage limiting circuit 9, connected in parallel between the power supply terminals B1 and B2, thus preventing too high a voltage between the power supply terminals of the corresponding subassembly. The voltage limiting circuits 9 are for example formed, in known manner, by diodes or transistors. For example, in FIG. 3, the voltage limiting circuit 9 is formed by a Zener diode, in FIG. 4 by a forward biased diode junction, and in FIG. 5 by a transistor-based device. Each subassembly can be composed of several elementary functional elements 10, connected in parallel between the power supply terminals B1 and B2. The elementary functional elements themselves comprise a large number of elementary transistors.

The particular internal architecture of an integrated circuit according to the invention enables the circuit to be supplied at voltages higher than or equal to the standard voltages (for example 3.3V) and ensures power supply of the different transistors with voltages much lower for example than one volt, while ensuring synchronization of the subassemblies due to the common clock.

Due to their series connection, all the subassemblies 2 are at different electrical potentials. The potential difference between the two end subassemblies is all the greater, compared with the supply voltage at the terminals of one of the subassemblies, the larger the number of subassemblies. Consequently, the subassemblies have to be separated by means for electric insulation. This electric insulation can be achieved in any known manner, for example by the use of reverse bias diode junctions and/or dielectric zones and/or by providing silicon blocks, isolated by dielectric zones, achieved from a silicon-on-insulator (SOI) substrate.

Transmission of the clock signal to the different subassemblies by the devices 6, 7 for shifting the clock signal levels (6a to 6d of FIG. 1 or 7a to 7e of FIG. 2) enables a very good synchronization to be ensured. The embodiment of FIG. 2 is a preferred embodiment, as it ensures a better synchronization of the subassemblies by principle. In the embodiment of FIG. 1, the devices 6 are in fact connected in series and cause summing of the time delays, whereas in the embodiment of FIG. 2, the devices 7 are connected in parallel and the time delays can be identical for each of the subassemblies.

If a subassembly tends at a given time to consume a little less current than the other subassemblies, as the current flowing through it is defined, the voltage at the terminals of the subassembly increases. This operating mode can be tolerated. If not, it can be adapted to include in each of the subassemblies a voltage limiting circuit 9 of the type described above, via which the excess current of the corresponding subassembly flows. This is why the invention is also particularly interesting when all the elementary functional elements 10 are identical in all the subassemblies: the consumptions are therefore then all identical. This is the case for example of SIMD (single instruction multiple data stream) type architectures.

Typically, on average this excess current should be less than 20% of the mean current flowing through the subassembly. In this case, it is then not problematic to dissipate the energy corresponding to this current and to the voltage of the subassembly.

For example, the voltage limiting circuit 9 can be formed by a Zener diode (FIG. 3), a forward biased diode junction (FIG. 4) or a controlled MOSFET type transistor (FIG. 5). The gate of the MOSFET can notably be controlled by the output of a voltage comparator comparing the voltage at the terminals of a subassembly with a reference voltage. Thus, for each subassembly, the voltage limiting circuit 9 can be integrated in the semi-conductor.

Likewise, the additional decoupling capacitor 8, which can be included in each subassembly, enables brief transient current differences between the subassemblies to be supplied or absorbed. These additional capacitors only have to supply or absorb a small part of the current pulses. On account of this, these capacitors of low value can be integrated in the semi-conductor. This additional decoupling function can be performed totally or partially by the stray capacitance of the subassembly and of the device used for voltage limiting. This represents a great advantage over the prior art which requires large energy storages to be performed in the decoupling capacitors on each subassembly.

An integrated circuit according to the invention can be supplied by a conventional switching power supply 3 with a voltage of five volts for example. The invention enables power supply in low voltage of each of the subassemblies 2 of the series of subassemblies to be performed. Each of the elements necessary for achieving the invention (the common clock circuit 5, the subassemblies 2, insulation of the subassemblies from one another, the voltage limiting circuit 9 of each subassembly, the decoupling means 8) can be achieved in a semi-conductor based integrated circuit and use a small part of the surface of the semi-conductor, which results in a small additional fabrication cost. A substrate of the SOI type is particularly well suited for achieving the invention.

To minimize the consumption of an integrated circuit according to the prior art, the elementary functional elements not used in a circuit can be disconnected from the power supply by transistors used as switches and the value of the supply voltage supplied to the integrated circuit by the switching power supply or by the step-down regulator dedicated to the integrated circuit can be controlled.

The consumption of a circuit according to the invention can be minimized by using one or more of the following means:
Disconnecting an unused elementary functional element 10 of a subassembly 2 from the power supply of this subassembly by opening transistors. The criterion of identical current consumption of the subassemblies does however have to be met. For example, in the case of identical subassemblies made up of identical elementary functional elements, it is preferable to isolate the same elementary functional element on each of the subassemblies at the same time.
Short-circuiting the power supply terminals B1 and B2 of a subassembly by an auxiliary transistor to cancel out the consumption of this subassembly and adapt the voltage supplied to the integrated circuit accordingly.
Adapting the voltage supplied to the integrated circuit by the switching power supply or the step-down converter supplying the integrated circuit.

Series connection of a large number of subassemblies is possible. Limitation of the number of subassemblies imposed by the regulations of the integrated circuit according to U.S. Pat. No. 5,703,790 does not exist.

1-15. (canceled)

16. Integrated circuit comprising at least a digital part comprising a large number of elementary transistors connected to one another so as to form a plurality of functional elements, the functional elements being grouped in subassemblies each comprising a first and a second electrical supply terminal and a clock input, the subassemblies being connected in series by means of their supply terminals to the terminals of a voltage supply source, integrated circuit wherein the clock input of each subassembly is connected to a common clock circuit and the clock input of at least one subassembly is connected to the common clock circuit by means of a device for shifting the levels of the clock signal.

17. Integrated circuit according to claim 16, wherein the subassemblies are formed in such a way that the sum of the instantaneous supply currents flowing through the functional elements of a subassembly is close to that of the other subassemblies.

18. Integrated circuit according to claim 16, wherein the clock inputs of at least two adjacent subassemblies are connected by a device for shifting the clock signal levels.

19. Integrated circuit according to claim 18, wherein the clock input of one of the end subassemblies is connected by means of an additional device for shifting the clock signal levels at the output of the clock circuit.

20. Integrated circuit according to any claim 16, wherein the device for shifting the clock signal levels comprises at least one capacitor.

21. Integrated circuit according to claim 16, wherein the device for shifting the clock signal levels comprises at least one transistor.

22. Integrated circuit according to claim 16, wherein all the subassemblies are identical.

23. Integrated circuit according to claim 16, wherein each of the subassemblies comprises a voltage limiting circuit connected between its power supply terminals.

24. Integrated circuit according to claim 23, wherein the voltage limiting circuit comprises a diode.

25. Integrated circuit according to claim 23, wherein the voltage limiting circuit comprises a transistor.

26. Integrated circuit according to claim 16, wherein each subassembly comprises a decoupling capacitor connected between the first power supply terminal and the second power supply terminal of the subassembly.

27. Integrated circuit according to claim 16, wherein the integrated circuit comprises means for electrical insulation between the subassemblies.

28. Integrated circuit according to claim 27, wherein the means for electrical insulation between the different subassemblies are reverse biased diode junctions.

29. Integrated circuit according to claim 27, wherein the means for electrical insulation between the different subassemblies are dielectric zones.

30. Integrated circuit according to claim 16, wherein the integrated circuit comprises silicon blocks achieved from a silicon-on-insulator substrate.
